(19) United States
(12) Patent Application Publication
(10) Pub. No.: US 2012/0090666 A1
(43) Pub. Date: Apr. 19, 2012

(54) SUPPORTS AND SYSTEM FOR SOLAR PANEL

(76) Inventor: Halston R. ROWE, Laguna Beach, CA (US)

(21) Appl. No.: 13/273,160

(22) Filed: Oct. 13, 2011

Related U.S. Application Data
(60) Provisional application No. 61/392,913, filed on Oct. 13, 2010.

(51) Int. Cl. H01L 31/048; F16B 1/00

(52) U.S. Cl. 136/251; 248/231.9

(57) ABSTRACT

A plurality of solar modules are connected to one another to form a solar panel. Each solar module has a frame. A support attached to the frame and a guide attaches to the guide to maintain the guide above the solar panel. A plurality of supports enable guides to traverse the solar panel in any desired configuration. Wires attached to the guides can therefore be placed anywhere about the solar panel in order to carry electricity generated by the solar panel, The supports include linear supports and right angle supports that support two guides that are perpendicular to one another.

### BACKGROUND OF THE INVENTION

Solar panels create usable energy from the sun. The solar panel may use the sun to heat a fluid, such as water, flowing through the solar panel. The heated fluid can be used as a source of hot water or used in radiators to heat a building, such as a house. Alternatively, the solar panel may be a photovoltaic panel that converts the sun's energy directly to electricity. The electricity then is used to power a building. Photovoltaic panels require wires extending through the panel to carry the generated electrical power. The wires must be attached to the panels in a manner that is both secure and stable but also easily accessible and replaceable in the event that repair or upgrades are necessary.

Previous solar panels have addressed the issue of securing wires to a solar panel, particularly when a plurality of smaller solar modules are connected to one another to form the larger panel. One such panel is disclosed in U.S. Pat. No. 6,465,724 to Garvison et al. The panel has photovoltaic modules 106 having side rails and end rails fastened together to form a rectangular frame 162. An L-shaped flange 190 defines an outer electrical wire raceway 194 through which jumper cables 196 run and an internal electrical wire raceway 202 accommodating wires 164, 166. The raceways of adjacent modules join together to allow the wires to traverse the full extent of the panel. The wires are concealed, increasing the difficulty of accessing the wires when they are in need of repair, replacement or installation after the modules have been joined to one another.

US 2008/0006321 to Munch et al. discloses photovoltaic modules having a plate module 2 supporting a base body 3. The base body 3 contains a contact element 5 and connection cables attach to and extend from the contact element in the base body 3. There is no support between the base bodies for the connection cables so that the connection cables must have enough rigidity to support themselves. In addition, the base body is connected to the top surface of the plate module in an unspecified manner. However, the attachment method must be strong enough to secure the base body to the module.

There is a need in the art for a system and method of securing wires to solar panels in a stable and secure manner that allows the wires to be repaired, replaced or added in a simple manner requiring few or no tools and able to be accomplished in a minimal amount of time.

It is an object of the invention to provide a system for securing wires to a solar panel in a secure, stable manner that is easy to maintain.

It is another object of the invention to provide supports for guides, the guides extending about the solar panel with wires attached to the guides.

It is still another object of the invention to provide supports for a solar panel that are easily attached and removed from the solar panel.

These and other objects of the invention will be apparent to one of ordinary skill in the art after reading the disclosure of the invention.

### SUMMARY OF THE INVENTION

The present invention provides a solar panel that includes an edge defining the perimeter of the solar panels, a plurality of guides extending over the solar panel for supporting or holding wires, the guides including a first guide and a second guide perpendicular to the first guide and at least one linear support connecting the first guide to the solar panel.

In one aspect, a right angle support connects the first guide to the second guide.

In another aspect, a plurality of modules are connected to one another to form the solar panel.

In another aspect, a frame extends about the perimeter of the solar panel, and the at least one linear support engages the frame to secure the at least one linear support to the solar panel.

In yet another aspect, the at least one linear support includes a body, an aperture extending through the at least one linear support for receiving a guide, and a groove extending across the body for receiving an edge of the frame.

In another aspect, the right angle support comprises a first aperture and a second aperture perpendicular to the first aperture.

In a further aspect, the right angle support further includes a first half and a second half, the first aperture formed by a first groove in the first half and a second groove in the second half, and the second aperture extending through the first half and the second half

### BRIEF DESCRIPTION OF THE DRAWINGS

FIG. 1 is a perspective view of a solar panel with a section shown in detail;

FIG. 2 is a perspective view of a linear support;

FIG. 3 is a perspective view of a right-angle support;

FIG. 4 is a perspective view of a two piece right angle support; and

FIG. 5 is an exploded view of the two piece right angle support.

### DETAILED DESCRIPTION OF THE INVENTION

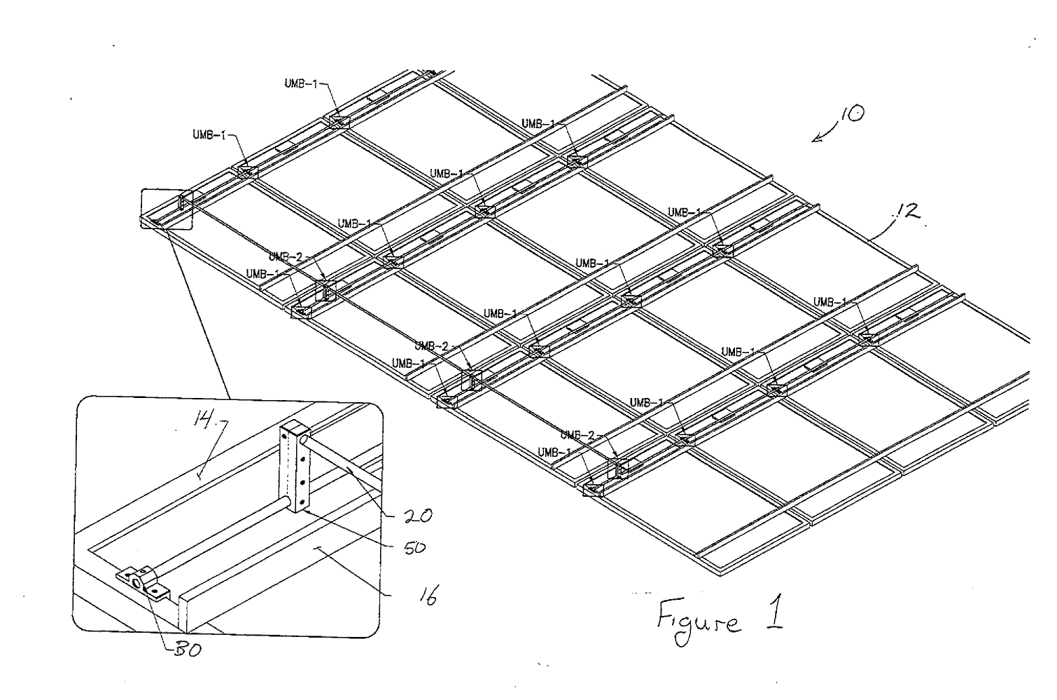

FIG. 1 depicts a solar panel 10 formed by a plurality of modules 12 connected to one another to form a panel. The use of modules allows the construction of a panel of any shape and size. The modules can be connected end to end to form a linear panel or formed end to end and side to side to form a rectangle or other shaped grid. Each module is bounded by a frame 14 and has at least one support rail 16. A series of guides 20 extend over the panel and are maintained above the panel by a series of supports. The supports are formed of any suitable material, such as aluminum. Wires are attached to the guides in any suitable manner. Attaching the wires to the guide, instead of within the guide, allows easy access to the wires and facilitates the wires making a right angle turn. The guides form a network extending across the panel, allowing wires to be placed anywhere along the panel. The wires remain accessible and are easily added, removed and repair when necessary.

The supports, to be described in more detail later, are easily attached at desired locations about the panel. Once the guides are secured to the supports, wires can be attached to the guides. The guides may be made of any suitable size, shape and material, such as a half inch aluminum rod. As seen in FIG. 1, the support rails 16 extend across several modules. By doing so, the support rail provides structural integrity to the panel. Also, the height of the support rails 16 can be selected to be the same height as the guides 20 extending transverse to the rails 16. In this manner, the support rails contribute to supporting the guides.

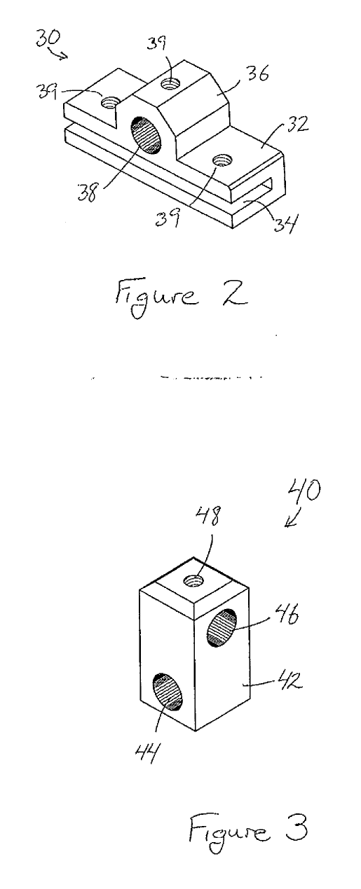

The first support located near a corner of the panel is a linear support 30. A linear support is best seen in FIG. 2. The linear support has a base 32 containing a groove 34 for securing to a panel. A protrusion 36 extends upwardly from the base 32 to provide enough height to accommodate an aperture 38. The size and the shape of the aperture 38 correspond to the size and shape of the guide 30 to be retained. While a circular aperture is shown, any other suitable shape, such as rectangular, triangular or square could be used. A plurality of set screw holes 39 are formed in the top surface of the linear connector 30, At least one set screw hole is formed in the base 32, the set screw hole extending to the groove to allow a set screw to secure the body to an edge of a panel. Another screw hole is formed in the protrusion 36 and extends to the aperture 38 to allow a set screw to secure a guide within the aperture. The set screw is shown in the top surface of the protrusion 36 but may be formed in a side surface.

As seen in the detailed view of FIG. 1, the groove 34 receives an edge of the module frame 14 to secure the support to the panel 12. The tightening of set screws in the set screw holes formed in the base 32 securely hold the support in place, but also allows for easy removal. A single guide 20 may extend through the aperture or ends of two guides 20 may each be retained within the aperture, so that the support not only maintains the guides over the panel but can connect two guides to one another. If two guides are held by a single support, it is advantageous to use two set screws, so that each guide is secured by a set screw.

As seen in the detailed view of FIG. 1, it is often desirable to have one guide extend perpendicularly to another. In that situation, a right angle support can be used. One type of right angle support is seen in FIG. 3. The right angle support 40 has a body with a first aperture 44 and a second aperture 46. The apertures may extend through the support so that the guide extends from both sides of the support. Needless to say, the apertures 44, 46 can be made any shape and side to match the cross section of the guides to be retained. Similar to the linear support 30, threaded apertures 48 in the body 42 allow set screws to secure the guides within the apertures. A set screw hole may be provided for the lower aperture 44 and a set screw hole 48 may be provided for the upper aperture 46. While the set screw hole 48 is shown in the top surface, the set screw hole may be formed in the side surface.

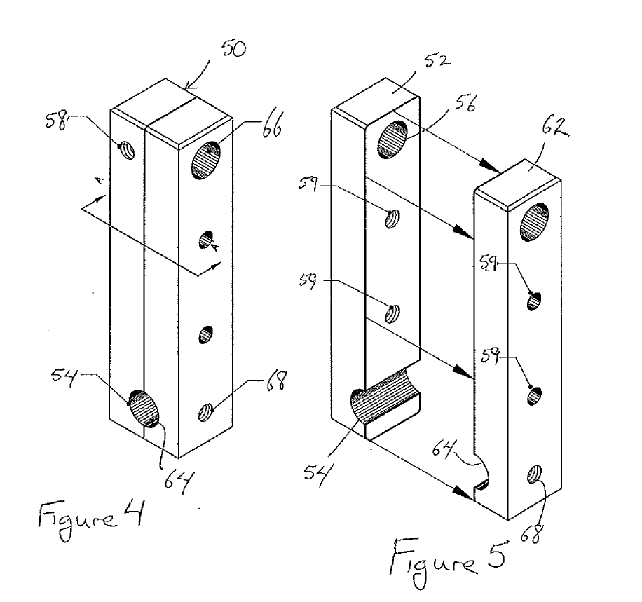

Situations may occur where it is desired to add a right angle support to a guide that is already in place. While it is always possible to remove the guide in order to add a right angle support 40 to the guide, it would be advantageous to be able to add a right angle support to an existing guide without needing to remove the guide. For such situations, a two piece right angle support 50, seen in FIGS. 4 and 5, may be utilized.

The two piece right angle support 50 has a first half 52 and a second half 62. The first half has a first groove 54 and a first aperture 56. Similarly, the second half has a second groove 64 and a second aperture 66. Each half has connector screw holes 59 allowing a screw (not shown) to secure the two halves together. When the two halves are connected, the two grooves 54, 64 form an aperture and the first aperture 56 and second aperture 66 align with one another to receive a guide. The first half 52 has a threaded hole 58 for a set screw and the second half 62 has a threaded hole 68 for a set screw. As can be readily understood, the threaded holes can be provided in either half. The two piece construction of the support allows one half to be placed on one side of a guide and the other half to be placed on the other side of a guide and then connected to one another so that the guide is enveloped by the two grooves 54, 64. Once secured, the perpendicular guide can be attached to the support 50 by placing the guide within the upper aperture 66.

While the invention has been described with reference to a preferred embodiment, variations and modifications would be apparent to one of ordinary skill in the art. The invention encompasses such variations and modifications.

1. A solar panel, comprising:
an edge defining the perimeter of the solar panels;
a plurality of guides extending over the solar panel, the guides including a first guide and a second guide perpendicular to the first guide; and
at least one linear support connecting the first guide to the solar panel.

2. The solar panel of claim 1, further comprising a right angle support connecting the first guide to the second guide.

3. The solar panel of claim 1, further comprising a plurality of modules connected to one another to form the solar panel.

4. The solar panel of claim 1, further comprising a frame about the perimeter of the solar panel, the at least one linear support engaging the frame to secure the at least one linear support to the solar panel.

5. The solar panel of claim 4, wherein the at least one linear support comprises:
a body;
an aperture extending through the at least one linear support for receiving a guide; and
a groove extending across the body for receiving an edge of the flame.

6. The solar panel of claim 1, wherein the right angle support comprises a first aperture and a second aperture perpendicular to the first aperture.

7. The solar panel of the claim 6, wherein the right angle support further comprises:
a first half and a second half;
the first aperture formed by a first groove in the first half and a second groove in the second half; and
the second aperture extending through the first half and the second half.

8. A linear support for supporting guides on a solar panel, comprising:
a body, the body having a base and a protrusion extending upwardly from a top surface of the base;
an aperture extending through the protrusion;
a groove extending across the body for receiving an edge of the solar panel; and
a plurality of set screws holes formed in the body, the set screw holes comprising:
at least one first set screw hole in the base, the set screw hole extending to the groove to allow a set screw to secure the body to an edge; and
a second screw hole formed in the protrusion and extending to the aperture to allow a set screw to secure a guide within the aperture.

9. The linear support of claim 8, wherein the second set screw is formed in a top surface of the protrusion.

10. The linear support of claim 8, further comprising:
a guide extending into the aperture, a cross sectional shape of the guide being the same shape as the aperture.

11. A right angle support, comprising
a body, the body having a first half and a second half;
a first aperture extending through the body and a second aperture extending through the body, the second aperture perpendicular to the first aperture;
the first aperture formed by a first groove in the first half and a second groove in the second half;
the second aperture extending through the first half and the second half; and
at least one screw securing the first half to the second half.
